(19) United States
(12) Patent Application Publication
(10) Pub. No.: US 2004/0206951 A1
(43) Pub. Date: Oct. 21, 2004

(54) Ion implantation in channel region of CMOS device for enhanced carrier mobility

(76) Inventors: Mohammad R. Mirabedini, Redwood City, CA (US); Agajan Suvkhanov, Portland, OR (US)

Correspondence Address: Intellectual Property Law Department, LSI Logic Corporation, Mail Stop D-106, 1551 McCarthy Boulevard, Milpitas, CA, 95035, US

(21) Appl. No.: 10/418,385

(22) Filed: Apr. 18, 2003

(51) Int. Cl. H01L 29/06

(52) U.S. Cl. 257/19

(57) ABSTRACT

An integrated circuit (IC) includes a CMOS device with a channel region that has ions implanted therein. The IC preferably incorporates sub-0.1 micron technology in the CMOS device. The implanted ions may preferably be germanium ions. The ion-implanted channel region preferably has a carrier mobility that is greater than that for a region that is not implanted with the ions.

### CROSS-REFERENCE TO RELATED APPLICATION

This invention is related to an invention for Ion Recoil Implantation and Enhanced Carrier Mobility in CMOS Device, described in U.S. patent application Serial No. (LSI Docket 02-6031), which is filed concurrently herewith, invented by the present inventors, and assigned to the assignee of the present invention. The subject matter of this concurrently filed application is incorporated herein by this reference.

### FIELD OF THE INVENTION

This invention relates to semiconductor integrated circuits (ICs) having IC components with sub-0.1 micron dimensions and implanted ions in the channel region of the components. In particular, this invention relates to ion implantation in the silicon of the channel region to enhance carrier mobility in the channel region. In this manner, relatively high performance requirements for CMOS (complimentary metal-oxide semiconductor) devices may be met without having to rely solely on scaling of the gate dielectric or of the channel length of the components.

### BACKGROUND OF THE INVENTION

A significant trend throughout IC development has been to reduce the size of the components of the IC's. As the size is reduced, the performance requirements of the materials of the components become more stringent. For CMOS devices (e.g. CMOS transistors) in particular, increased performance requirements have generally been met by aggressively scaling the thickness and/or dielectrical properties of the gate dielectric and the length of the channel of the transistors. As attempts have been made to scale down CMOS technology into the sub-0.1 micron dimensions, however, the performance requirements for the CMOS devices have proven to be so stringent that the technique of scaling either the gate dielectric or the channel length or both has been a very difficult and/or impractical solution for meeting the high performance requirements.

To meet the increased performance requirements of the smaller CMOS devices, it has been suggested to alter characteristics other than the gate dielectric and/or channel length of the devices. One such characteristic for which improvements have been suggested is the mobility of the carriers in the channel region. For example, strained silicon (SSI) may be incorporated into the channel region, since strained silicon is known to have greater carrier mobility characteristics than do the materials that have been more commonly used in the channel region of CMOS devices. (K. Rim, S. Koester, M. Hargrove, J. Chu, P. M. Mooney, J. Ott, T. Kanarsky, P. Ronsheim, M.leong, A. Grill, and H.-S. P. Wong, “Strained Si NMOSFETs for High Performance CMOS Technology,” 2001 Symposium on VLSI Technology Digest of Technical Papers, 2001, p. 59.)

Formation of a strained silicon layer on a semiconductor wafer may be done in a variety of ways. One technique involves complex fabrication processes, which includes epitaxial growth steps, such as epitaxial growth of a relatively thick silicon-germanium (SiGe) film 100 onto a silicon substrate 102 and epitaxial growth of a strained silicon layer 104 onto the SiGe film 100, as shown in FIGS. 1, 2 and 3. The strain in the silicon is induced by the underlying SiGe film. The SiGe film 100 is typically formed with a graded concentration of Ge in the Si, wherein the concentration of the Ge is slowly increased as the SiGe film 100 is grown on the substrate 102. In order to produce high quality strained silicon it is essential to carefully control the stoichiometry of the layer during the growth process. Thus, the introduction of the gases into the epitaxial growth chamber (not shown) must be carefully varied during fabrication of the SiGe film 100. In this manner, the spacing between the atoms in the crystalline structure of the SiGe film 100 is slowly increased from the beginning 106 to the surface 108 of the SiGe film 100. When the strained Si layer 104 is epitaxially grown on top of the SiGe film 100 (FIG. 2), the strain is effectively maintained between the Si atoms. A conventional CMOS transistor 110 (FIG. 3), having a conventional source, drain, gate and gate oxide region 112, 114, 116 and 118, is then fabricated on top of the strained Si layer 104. The increased spacing between the Si atoms in the strained Si layer 104 enhances the mobility of the carriers in the channel region, which is formed in the strained silicon layer 104 under the gate oxide 118 and between the source and drain 112 and 114.

The epitaxial growth steps increase the time and cost of fabrication required to form the IC. Thus, there is a tradeoff between the performance characteristics and the cost of the resulting IC. Additionally, the presence of the strained Si layer 104 sets limitations on the temperatures at which any subsequent processing steps may be performed, thereby limiting the flexibility with which the subsequent processing steps may be performed. Furthermore, the SiGe film 100 acts as a thermal insulation layer, so the CMOS transistors formed thereon are susceptible to self-heating during operation of the IC, thereby degrading the performance capability of the IC. Also, isolation of the CMOS transistor 110, typically with shallow trench isolation, must be defined in both the strained Si layer 104 and the SiGe film 100 as well as in the silicon substrate 102, which adds to the complexity of the overall IC fabrication. Furthermore, this technique is prone to defects, which may occur in the SiGe film 100 and, thus, propagate into the strained Si layer 104 and higher layers of materials. Such defects may involve threaded dislocations in the crystalline structure of the various layers that negatively impact carrier mobility, gate oxide quality and overall device performance.

It is with respect to these and other considerations that the present invention has evolved.

### SUMMARY OF THE INVENTION

The present invention involves ion implantation into a silicon (Si) substrate to enhance carrier mobility in the channel region of CMOS devices in an integrated circuit (IC). Heretofore, such ion implantation has been known to be used to enhance source and drain performance in CMOS devices as a pre-amorphization step, but has not been used to affect channel performance. By enhancing carrier mobility in the channel according to the present invention, however, the increased performance requirements of sub-0.1 micron CMOS technology can be met by an incremental increase in device performance with only a relatively simple fabrication modification that does not substantially increase the time or cost of fabrication of the IC. A preferred ion to be used in this invention is germanium (Ge), although other appropriate ion species may be used, depending on the application.

Carrier mobilities are higher in Ge and its alloys than in the Si conventionally used in the channel regions of CMOS devices. Thus, the Ge-implanted Si, when used for the channel region of a CMOS device, allows for greater carrier mobility in the channel region, though the mobility improvement is generally not as great as for the strained Si techniques described above.

The present invention does not have the complexity, time and cost problems of the strained Si technique described in the background, since the Ge ion implantation can be performed in a single implantation step. Additionally, the present invention does not have the process temperature limitations or the self-heating problems described above. Therefore, although the carrier mobility improvement for the present invention is generally not as great as for the strained Si techniques, greater simplicity and fewer problems make the present invention an improvement over the strained Si techniques.

These and other aspects and improvements of the present invention are accomplished in an IC and a method of forming an IC having a CMOS device formed on a semiconductor substrate having ions implanted in the channel region of the CMOS device. The ions are implanted into a region of the substrate, and the CMOS device is formed on the implanted region of the substrate. In this manner, the channel region of the CMOS device is within the region of the substrate implanted with the ions.

According to additional embodiments of the present invention, the IC may preferably incorporate sub-0.1 micron technology. Furthermore, the ion may preferably be germanium or other appropriate ion that causes the implanted region of the substrate to have a carrier mobility greater than any non-implanted region of the substrate.

Additionally, in other embodiments of the present invention, the ion-implanted region of the substrate may preferably have an ion concentration gradation that increases with distance from the surface of the substrate. In this manner, the surface of the substrate may preferably have, a low or zero concentration of the ion, so that a gate oxide may be relatively easily grown on the surface of the substrate. For higher concentrations of the ion at the surface of the substrate, the gate oxide may be deposited, rather than grown, on the surface of the substrate.

A more complete appreciation of the present invention and its scope, and the manner in which it achieves the above noted improvements, can be obtained by reference to the following detailed description of presently preferred embodiments of the invention taken in connection with the accompanying drawings, which are briefly summarized below, and the appended claims.

### BRIEF DESCRIPTION OF THE DRAWINGS

FIGS. 1-3 are simplified, broken, cross-sectional views of portions of a prior art integrated circuit, which show prior art steps involved in the fabrication of the prior art integrated circuit.

FIG. 4 is a simplified, broken, cross-sectional view of a portion of an integrated circuit in which the present invention is incorporated and which has been fabricated according to the present invention.

FIG. 5 is a simplified, broken, cross-sectional view of portions of the integrated circuit shown in FIG. 4 showing an intermediate step involved in the fabrication of the integrated circuit.

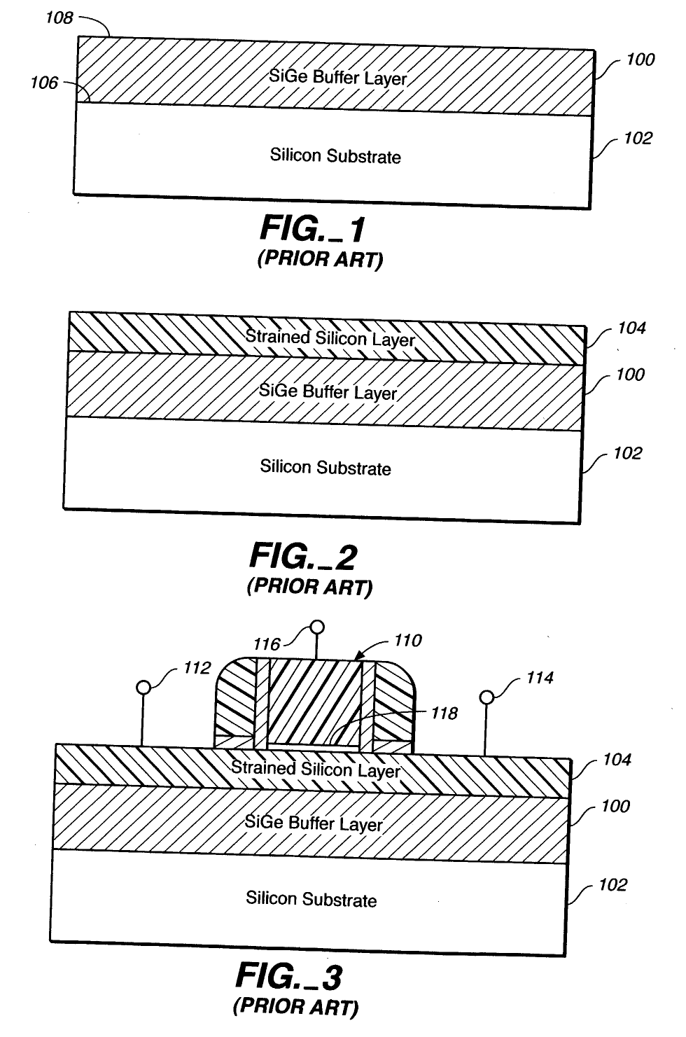

### DETAILED DESCRIPTION

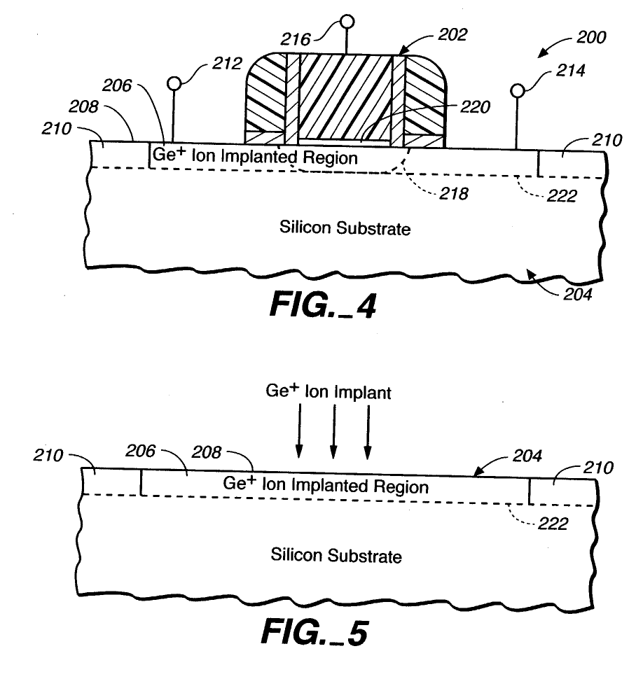

A portion of an integrated circuit (IC) 200 which incorporates the present invention and which is formed by the methodology of the present invention is shown in FIG. 4. The IC 200 includes a CMOS device 202 (such as a conventional CMOS transistor) formed on a silicon (Si) substrate 204 preferably, though not necessarily, with sub-0.1 micron technology. The Si substrate 204 generally includes an ion-implanted region 206 that extends below the surface 208 of the Si substrate 204. The Si substrate 204 may also include a conventional non-implanted region 210. The CMOS device 202 generally includes a source 212 and a drain 214 which are formed on the Si substrate 204. A gate 216 separates the source 212 and the drain 214. When the CMOS device is activated during operation of the IC 200, the source 212 and the drain 214 are electrically connected by a channel 218, which extends in the Si substrate 204 between the source 212 and the drain 214 more or less primarily through the ion-implanted region 206 of the Si substrate 204. The gate 216 is separated by and insulated from the channel 218 by a gate dielectric region or layer 220.

The ion-implanted region 206 may be either N channel or P channel and is implanted with ions, such as germanium (Ge⁺) ions, as shown in FIG. 5. The implanted ions promote the carrier mobility enhancement characteristics in the Si substrate 204. Additionally, the presence of the ions in the Si may cause Si atoms near the surface 208 of the Si substrate to be “slightly” strained, thereby further enhancing carrier mobility. With the implanted ions, therefore, the carrier mobility in the ion-implanted region 206 (and therefore in the channel 218) is higher than for the non-implanted region 210, so the length of the channel 218 and the thickness and/or composition of the gate dielectric region 220 do not have to be scaled too aggressively and the complex and costly techniques described in the background do not have to be used.

The dose of the ions and the energy level for an ion implantation procedure to form the ion-implanted region 206 generally depend on the desired transistor performance. For example, a dose range of 2E14-1E15 atm/cm² with low energies of 8-15 keV may be used in an ion implantation procedure to form the ion-implanted region 206 at the top of the Si substrate 204. This procedure may form a SiₓGel₁₋ₓ film of about 80-200 Angstroms thick, possibly with a very thin (e.g. less than 100 Angstroms) layer of strained Si near the surface 208. After the implantation procedure, an anneal cycle is generally needed to re-crystallize the film and remove damages caused by the implantation. Then the CMOS device 202 may be formed on top of the ion-implanted region 206 using conventional fabrication techniques, such as those for sub-0.1 micron technology devices.

The implantation procedure generally results in the ion-implanted region 206 having a graded concentration of the ions in the Si. The ion concentration is generally very low at or near the surface 208 of the Si substrate 204 and increases downwards until tapering off near the bottom 222 of the ion-implanted region 206.

If the concentration of the Ge at the surface 208 of the Si substrate 204 is sufficiently low, then the gate dielectric region 220 can preferably be grown on top of the ion-implanted region 206. On the other hand, if the concentration of Ge is higher (e.g. if needed for higher carrier mobility), then the gate dielectric region 220 may be deposited, instead of grown, on top of the ion-implanted region 206.

It is apparent from the previous description that the present invention permits the fabrication of CMOS devices, particularly sub-0.1 micron technology devices, without the complex and costly procedures suggested in the prior art. Though the enhancement in the carrier mobility may not be as great as in the prior art, the enhancement is sufficient to enable a low-cost alternative to the prior art. The present invention can also be tailored for selective introduction of the ions into both N channel and P channel device regions with different ion doses as necessary to achieve an optimized CMOS device performance in a variety of applications. Additionally, the present invention may be used for devices built on SOI (silicon-on-insulator) or other thin film technologies. Also, isolation of the CMOS device 202 (e.g. shallow trench isolation) is relatively easily accomplished. Many other advantages and improvements will be apparent after gaining a complete appreciation of the present invention.

Presently preferred embodiments of the present invention and many of its improvements have been described with a degree of particularity. This description is of preferred examples of implementing the invention, and is not necessarily intended to limit the scope of the invention. The scope of the invention is defined by the following claims.

The invention claimed is:

1. A method of forming an integrated circuit comprising:
providing a substrate;
implanting ions into a region of the substrate; and
forming a CMOS device on the region of the substrate implanted with the ions, the CMOS device having a channel region, at least a part of which is formed by at least a part of the region of the substrate implanted with the ions.

2. A method as defined in claim 1 further comprising:
implanting germanium ions into the region of the substrate.

3. A method as defined in claim 1 further comprising:
forming the region of the substrate implanted with the ions to have a carrier mobility greater than a carrier mobility of a region of the substrate that is not implanted with the ions.

4. A method as defined in claim 1 further comprising:
forming the CMOS device with sub-0.1 micron technology.

5. A method as defined in claim 1 further comprising:
implanting the ions into the region of the substrate in a graded concentration having a lowest concentration near a surface of the substrate.

6. A method as defined in claim 5 further comprising:
growing a gate dielectric region of the CMOS device on the region of the substrate implanted with the ions.

7. A method as defined in claim 5 further comprising:
depositing a gate dielectric region of the CMOS device on the region of the substrate implanted with the ions.

8. A method as defined in claim 1 further comprising:
implanting the ions into the region of the substrate with an almost zero concentration of the ions at a surface of the substrate.

9. A method as defined in claim 1 further comprising:
implanting the ions into the region of the substrate with a single ion implantation step.

10. A method of forming an integrated circuit comprising:
providing a substrate having a first carrier mobility;
implanting ions into the substrate to form an implanted region of the substrate, the implanted region of the substrate having a second carrier mobility due to the implanted ions, the second carrier mobility being greater than the first carrier mobility; and
forming a CMOS device on the implanted region of the substrate, the CMOS device having a channel region, at least a part of which is formed by at least a part of the implanted region of the substrate.

11. A method as defined in claim 10 further comprising:
implanting germanium ions into the substrate to form the implanted region of the substrate.

12. A method as defined in claim 10 further comprising:
forming the CMOS device with sub-0.1 micron technology.

13. A method as defined in claim 10 further comprising:
implanting the ions into the implanted region of the substrate with a single ion implantation step.

14. A method as defined in claim 10 further comprising:
implanting the ions into the implanted region of the substrate in a graded concentration having a lowest concentration near a surface of the substrate.

15. A method as defined in claim 14 further comprising:
growing a gate dielectric region of the CMOS device on the implanted region of the substrate.

16. A method as defined in claim 14 further comprising:
depositing a gate dielectric region of the CMOS device on the implanted region of the substrate.

17. An integrated circuit comprising:
a substrate having a surface;
an ion-implanted region of the substrate; and
a CMOS device formed on the surface of the substrate and having a channel region within the substrate, at least a part of the channel region being formed by at least a part of the ion-implanted region of the substrate.

18. An integrated circuit as defined in claim 17 wherein the ion-implanted region of the substrate is a germanium ion-implanted region.

19. An integrated circuit as defined in claim 17 wherein the CMOS device is formed with sub-0.1 micron technology.

20. An integrated circuit as defined in claim 17 wherein:
the ion-implanted region of the substrate includes ions in a graded concentration having a lowest concentration near the surface of the substrate.
